(19) United States
(12) Patent Application Publication
(10) Pub. No.: US 2018/0195492 A1
(43) Pub. Date: Jul. 12, 2018

(54) Device for Generating Energy and Method for Use of the Device

(71) Applicant: Janjaap Ruijssenaars, Amsterdam (NL)

(72) Inventors: Janjaap Ruijssenaars, Amsterdam (NL); Jan Holterman, Delden (NL); Theodorus Jacobus Adrianus De Vries, Enschede (NL)

(21) Appl. No.: 15/740,863

(22) PCT Filed: Jun. 27, 2016
(86) PCT No.: PCT/NL2016/050454

§ 371 Date: Dec. 29, 2017

(30) Foreign Application Priority Data
Jul. 2, 2015 (NL) 2015077

(51) Int. Cl. F03D 5/06; H02N 2/18; H01L 41/113; F03D 9/25

(52) U.S. Cl. CPC F03D 5/06; H02N 2/185; F05B 2220/709; H01L 41/113; F03D 9/25; H02N 2/186

(57) ABSTRACT

The invention relates to a device for generating energy, which includes an inverted pendulum having an arm oscillating about a pivot point and a mass arranged on the arm and spring means preserving the equilibrium of the inverted pendulum. The spring means includes at least one piezo generator for generating energy from the oscillating movement. The invention also relates to a method for use of a device according to the invention.

The invention relates to a device for generating energy, which device comprises:

an inverted pendulum comprising an arm oscillating about a pivot point and a mass arranged on the arm;

spring means for preserving the equilibrium of the inverted pendulum.

With an inverted pendulum the mass is located above the pivot point, as seen in the direction of the gravitational force. Such an inverted pendulum is by definition unstable. The inverted pendulum can be held in a neutral position by adding spring means, such as for instance a coil spring or torsion spring, around the pivot point of the oscillating arm. However, as soon as the equilibrium of the pendulum is disturbed by an external force, the pendulum will oscillate back and forth and will be returned to the neutral position by the spring means.

Because of the mass arranged on the oscillating arm, it will take only a small external force for a powerful oscillating movement to occur as a result of the force of gravity engaging on the mass.

The small external force can for instance be a gust of wind, a vibration of a vehicle or an external magnetic force. Alternatively, it is however also possible here to envisage for instance rain, waves or ambient vibrations.

It is now an object of the invention to use energy from the powerfully oscillating movement, caused by the small external force, for other purposes in the device stated in the preamble.

This object is achieved according to the invention with a device according to the preamble, which device is characterized in that the spring means comprise at least one piezo generator for generating energy from the oscillating movement.

A piezo generator comprises a piezo material which generates electrical energy by deformation, which electrical energy can be used for other purposes.

The amount of electrical energy is dependent on the extent to which the piezo material is deformed. When engaging directly on the piezo material, a small external force can cause only a small deformation and thereby generate only a limited amount of electrical energy.

Because an inverted pendulum is used, the force of the oscillating movement, which is caused in that the small external force, such as a gust of wind, disturbs the equilibrium of the pendulum, can however be used to deform the piezo material. Since the oscillating movement is more powerful than the small external force, energy of the gust of wind can be converted into electrical energy more efficiently.

By exerting a force on piezo material, the material will deform and a change in length substantially proportional to the force exerted will occur. This corresponds to a linear spring, whereby piezo material can for the sake of convenience also be assigned a spring constant, with which the relation between exerted force and deformation can be represented.

In a preferred embodiment the at least one piezo generator is a spring means for preserving the equilibrium of the inverted pendulum, in so far as this was not yet apparent from the foregoing. In other words, without the presence of the piezo generator, the inverted pendulum would be unstable and fall over because the piezo generator provides for and guarantees the stability of the system. A way in which this can be achieved is in that the inverted pendulum makes contact with the ground substantially or only via the piezo generator, for instance because the pendulum is positioned on top of the piezo generator. The efficiency of the piezoelectric conversion is in this way increased by the influence of the force of gravity on the mass.

The skilled person will recognize here that the fact that the oscillating movement is more powerful than the small external force is the result of the gravity engaging or acting on the mass.

In another preferred embodiment of the device it is the case that mgl.sin α<K. α

wherein:

m is the mass arranged on the arm

g is the gravitational acceleration

l is the distance from the mass to the pivot point

K is the spring constant of the spring means including the spring constant of the at least one piezo generator

α is the angle of the arm to the direction of the force of gravity.

As mgl.sin α approaches K. α more closely, it becomes more easily possible to bring the inverted pendulum into an unstable situation by means of an external force.

Through a suitable choice of particularly the mass and the spring constant in relation to the anticipated maximal external force, the inverted pendulum can be optimized such that a maximum deflection of the pendulum is obtained at the anticipated external force, such as a gust of wind. This maximum deflection ensures that the piezo generator is deformed maximally and the conversion of the external force into electrical energy is thereby optimized.

When mgl.sin α>K. α the inverted pendulum will be unstable and fall over. The pendulum will thus not return to a neutral position in which the pendulum can be impacted again.

Another embodiment of the device comprises at least two piezo generators arranged diametrically opposite each other relative to the pivot point.

By arranging at least two piezo generators on either side of the pivot point, the external force can come from opposite directions to disturb the equilibrium of the device.

When at least three piezo generators are used, the three generators can be placed in a triangle, whereby the device can oscillate in two mutually perpendicular directions. When the device is activated by for instance wind, the device is no longer dependent on the wind direction owing to this configuration.

When a plurality of piezo generators is used, it should be noted that the piezo generators are arranged on a circular path, in so far as this was not yet apparent from the foregoing. As a result hereof, the mass performs a rotating movement on the piezo generators, subject to the direction of engagement of the small external force.

A preferred embodiment of the device according to the invention further comprises a base and a support plate arranged parallel to the base, wherein the at least two piezo generators are arranged between the base and the support plate and wherein the arm is arranged perpendicularly of the support plate.

Such an embodiment can be manufactured easily and inexpensively, while the embodiment can also be easily adjusted to the anticipated external forces, such as wind, by adjusting the mass and by adjusting the position of the mass on the arm relative to the pivot point.

It is also possible that the piezo generators are in an embodiment of the device not arranged on a base, but positioned loosely on a ground surface. If the bottom surface is sufficiently wide, the pendulum can oscillate back and forth within the width of the bottom surface. The piezo generators will be alternately compressed here.

Yet another preferred embodiment of the device according to the invention further comprises a battery and an electrical circuit for charging the battery with the energy generated by the at least one piezo generator. The electrical circuit preferably consists of passive components.

Since the electrical energy generated by the piezo generators is dependent on the size of the external force and the frequency of said force, it is advantageous to store this energy in a battery. With the battery the energy can then be used again at another moment.

Another preferred embodiment of the device according to the invention further comprises a wind-break arranged on the free end of the arm.

The arm can catch more wind with the wind-break, whereby the external force will be greater, whereby the oscillating movement of the inverted pendulum can be more powerful.

The invention further relates to a method for use of a device according to the invention, comprising the steps of:

providing a device according to the invention;

deforming the at least one piezo generator of the device with a small force, such as for instance a gust of wind, a vibration of a vehicle, an external magnetic force, rain, waves or ambient vibrations, and under the influence of the force of gravity.

extracting from the piezo generator the energy obtained by the deformation.

These and other features of the invention are further elucidated with reference to the accompanying figures.

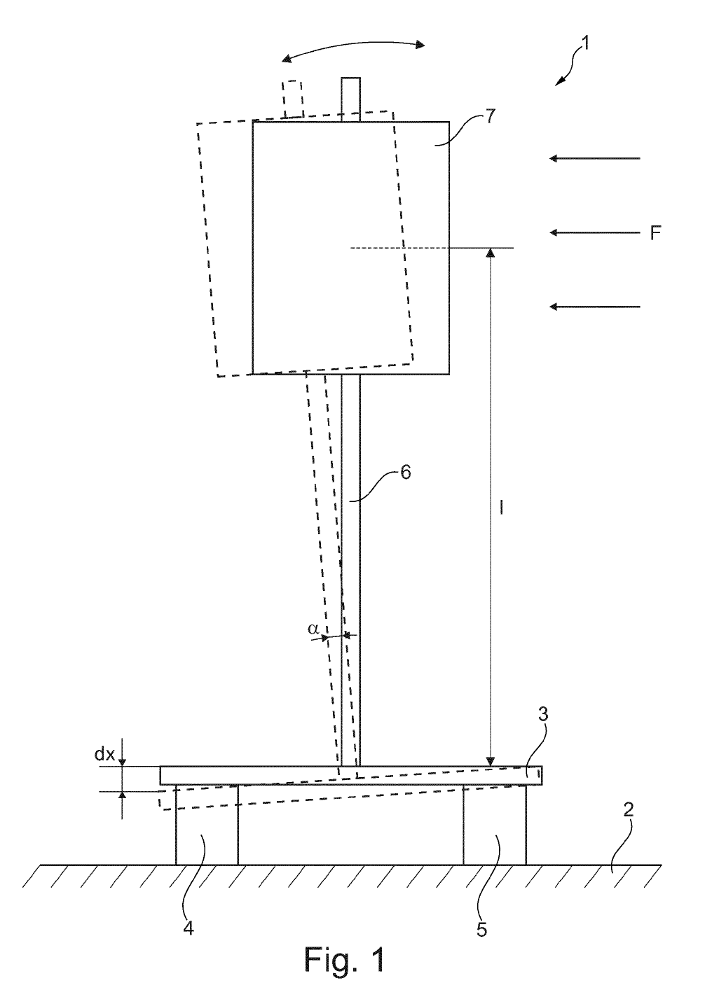

FIG. 1 shows an embodiment of the device according to the invention.

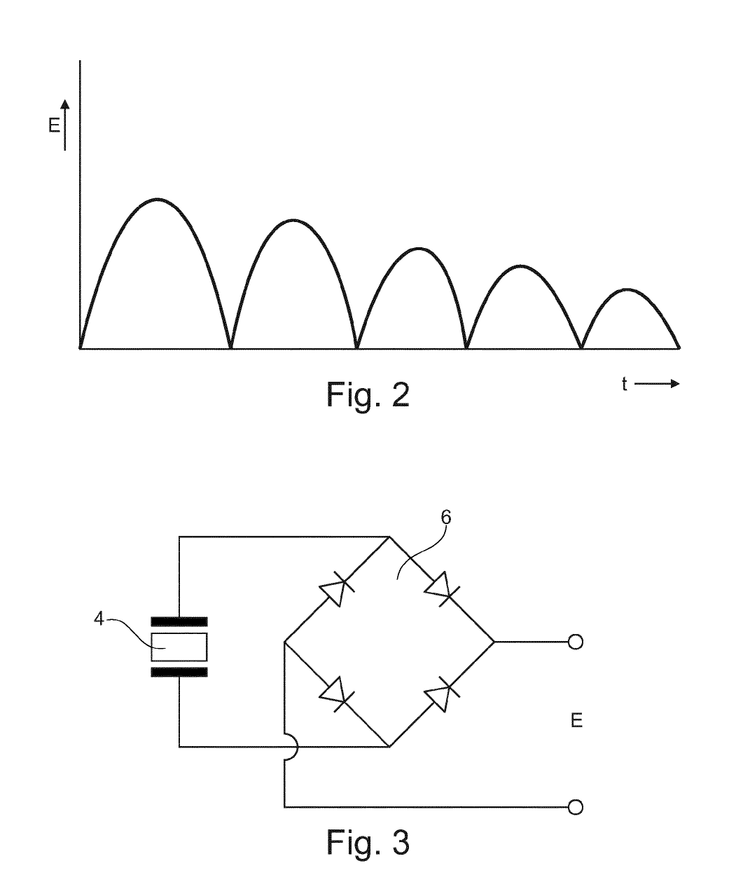

FIG. 2 shows schematically the energy generated by a piezo generator as a result of a brief external force.

FIG. 3 shows schematically the circuit of a piezo generator with a rectifier bridge.

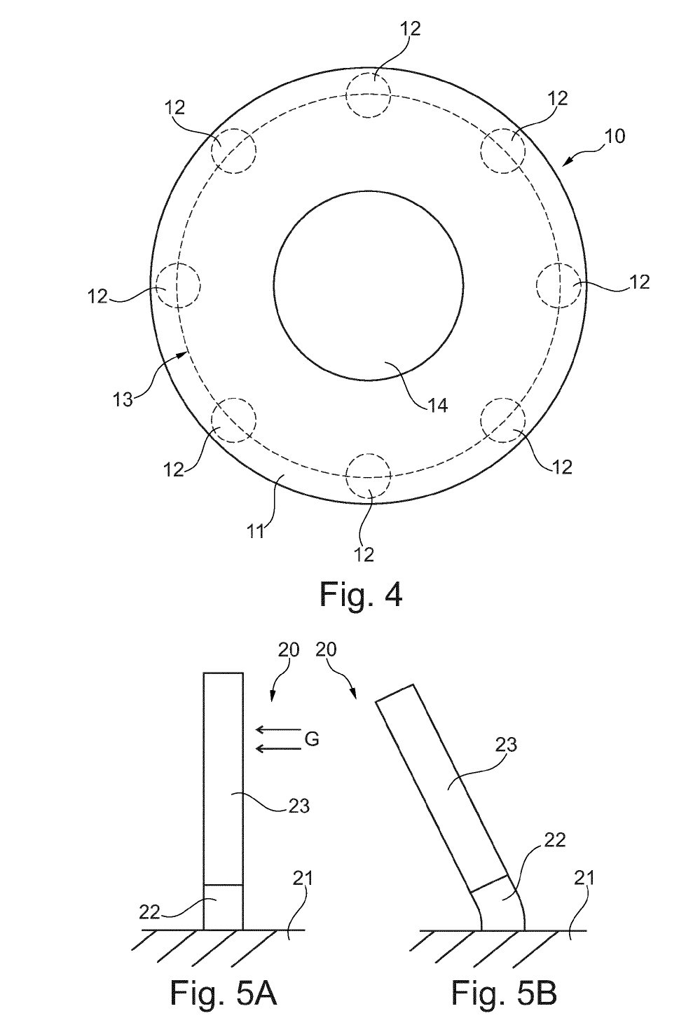

FIG. 4 shows a top view of an embodiment of a device according to the invention.

FIGS. 5A and 5B show an embodiment of a device according to the invention in respectively a neutral position and a position in which it is not in equilibrium.

FIG. 1 shows an embodiment of device 1 according to the invention. Device 1 has a base 2 and a support plate 3 arranged parallel thereto. Arranged between base 2 and the support plate are two piezo generators 4, 5, both having a resilient property as a result of the piezo material. An arm 6 with a mass 7 at the free end is positioned perpendicularly of support plate 3.

When a gust of wind F presses against mass 7, the equilibrium of arm 6 will be disturbed and the arm will start oscillating about the neutral position, which is drawn in full lines in FIG. 1.

Due to the oscillating movement of mass 7 and arm 6 piezo generators 4, 5 will be alternately compressed over a certain distance dx. When the one piezo generator 4 is compressed, the other piezo generator 5 will meet with less pressure or will even expand slightly. Because piezo generators 4, 5 act as a spring, the oscillating movement of arm 6 and mass 7 will be slowed down and device 1 will once again return to the neutral position.

In order to ensure that device 1 returns once again to the neutral position, it is necessary to comply at least with mgl.sin α<K. α. m is here the mass 7, g the gravitational acceleration (typically 9.8 m/s²), l the distance from the centre of gravity of mass 7 to the pivot point of support plate 3. α is the angle of arm 6 to the direction of the force of gravity and K is the spring constant around the pivot point of support plate 3. This spring constant K is put together from the spring constants of piezo generators 4, 5. Although not recommended, additional spring elements can further optionally be provided in order to obtain a desired spring constant, wherein the equilibrium of the pendulum cannot be disturbed.

FIG. 2 shows schematically the energy E generated by piezo generators 4 plotted against the time t, from the moment that the force F disturbs the equilibrium of device 1. The energy E of the piezo generator is rectified here by a rectifier bridge 6, as shown in FIG. 3.

Because of the spring constant K device 1 will return once again to a neutral position after a number of oscillations, which is shown in FIG. 2 by the decreasing amplitude.

It is also apparent from FIG. 2 that it is not easy to use the energy E directly to provide an electrical component, such as for instance a lamp, with current. The lamp will flash during oscillation of device 1.

In order to equalize these fluctuations in the generated energy, a control can be provided which uses energy to charge a battery. The battery can then provide a constant current which can power for instance a lamp to be on continuously.

FIG. 4 shows an embodiment 10 of a device according to the invention. A base 11 is shown under which a number of piezo generators 12 are arranged with the centres distributed evenly on a circular path 13, on which generators the base 11 rests in the centre of path 13. On the upper side of base 11 a mass 14 is arranged in the centre of path 13.

FIGS. 5A and 5B show an embodiment 20 of a device according to the invention. In FIG. 5A the device 20, which is constructed from a piezo generator 22 fixed to ground 21 and a rigid mass 23 mounted thereon, is in the neutral position. At the moment that force G acts on rigid mass 23, device 20 will take on the position shown in FIG. 5B, in which it is temporarily not in equilibrium. Piezo generator 22 is deformed here. The energy from this conversion can be used. The gravity acting on mass 22 hereby ensures an efficient conversion.

Known in addition from the publication WO 2014/135551 A1 is an inverted pendulum comprising an arm oscillating about a pivot point and a mass arranged on the arm, and also comprising a piezo generator, although it is here not the piezo generator which preserves the equilibrium of the inverted pendulum.

1. A device for generating energy comprising:
an inverted pendulum comprising an arm oscillating about a pivot point and a mass arranged on the arm; and
a spring preserving the equilibrium of the inverted pendulum;
wherein the spring comprises at least one piezo generator for generating energy from the oscillating movement.

2. The device as claimed in claim 1, wherein the at least one piezo generator is a spring preserving the equilibrium of the inverted pendulum.

3. The device as claimed in claim 1, wherein mgl.sin α<K. α
wherein:
m is the mass arranged on the arm
g is the gravitational acceleration
l is the distance from the mass to the pivot point
K is the spring constant of the spring including the spring constant of the at least one piezo generator
α is the angle of the arm to the direction of the force of gravity.

4. The device as claimed in claim 1, comprising at least two piezo generators arranged diametrically opposite each other relative to the pivot point.

5. The device as claimed in claim 4, comprising a base and a support plate arranged parallel to the base, wherein the at least two piezo generators are arranged between the base and the support plate and wherein the arm is arranged perpendicularly of the support plate.

6. The device as claimed in claim 1, further comprising a battery and an electrical circuit for charging the battery with the energy generated by the at least one piezo generator.

7. The device as claimed in claim 1, further comprising a wind-break arranged on the free end of the arm.

8. A method for use of a device as claimed in claim 1, comprising:
providing the device;
deforming the at least one piezo generator of the device with a small force; and
extracting from the piezo generator the energy obtained by the deformation.

9. The method as in claim 8, wherein the small force comes from at least one of: a gust of wind, a vibration of a vehicle, an external magnetic force, rain, waves or ambient vibrations, and force of gravity.

10. The device as claimed in claim 2, wherein mgl.sin α<K. α
wherein:
m is the mass arranged on the arm
g is the gravitational acceleration
l is the distance from the mass to the pivot point
K is the spring constant of the spring including the spring constant of the at least one piezo generator
α is the angle of the arm to the direction of the force of gravity.

11. The device as claimed in claim 3, comprising at least two piezo generators arranged diametrically opposite each other relative to the pivot point.

12. The device as claimed in claim 3, further comprising a battery and an electrical circuit for charging the battery with the energy generated by the at least one piezo generator.

13. The device as claimed in claim 4, further comprising a battery and an electrical circuit for charging the battery with the energy generated by the at least one piezo generator.

14. The device as claimed in claim 5, further comprising a battery and an electrical circuit for charging the battery with the energy generated by the at least one piezo generator.

15. The device as claimed in claim 3, further comprising a wind-break arranged on the free end of the arm.

16. The device as claimed in claim 4, further comprising a wind-break arranged on the free end of the arm.

17. The device as claimed in claim 5, further comprising a wind-break arranged on the free end of the arm.

18. The device as claimed in claim 6, further comprising a wind-break arranged on the free end of the arm.
